(19) United States
(12) Patent Application Publication
(10) Pub. No.: US 2007/0258298 A1
(43) Pub. Date: Nov. 8, 2007

(54) Parallel programming of flash memory during in-circuit test

(75) Inventors: Greg Amidon, Schaumburg, IL (US); Samil Asim Addemir, Naperville, IL (US); Greg Topham, Batavia, IL (US)

Correspondence Address: MCDONNELL BOEHNEN HULBERT & BERGHOFF LLP, 300 S. WACKER DRIVE, 32ND FLOOR, CHICAGO, IL, 60606, US

(73) Assignee: Westell Technologies, Inc., Aurora, IL (US)

(21) Appl. No.: 11/453,632

(22) Filed: Jun. 15, 2006

Related U.S. Application Data
(60) Provisional application No. 60/797,716, filed on May 4, 2006.

(51) Int. Cl. G11C 16/06; G11C 11/34; G11C 29/00; G11C 7/00; G11C 16/04

(52) U.S. Cl. 365/201; 365/185.09; 365/185.28

(57) ABSTRACT

A method and system for parallel programming flash devices during in-circuit testing is described. A parallel processing device is located in a test fixture of an In-Circuit Tester (ICT) for each printed circuit board (PCB) connected to the test fixture. The parallel processing device controls the communications between the ICT and the PCB. The parallel processing device facilitates parallel programming of flash devices that passed in-circuit testing. The parallel processing device prevents programming of flash devices that failed in-circuit testing.

### PRIORITY

The present patent application claims priority under 35 U.S.C. § 119(e) to U.S. Provisional Patent Application Ser. No. 60/797,716, which was filed May 4, 2006. The full disclosure of U.S. Provisional Patent Application Ser. No. 60/797,716 is incorporated herein by reference.

### RELATED APPLICATIONS

This application is related to the following concurrently filed U.S. Applications, which are incorporated by reference herein:
U.S. patent application Ser. No. ______; filed on Jun. 15, 2006, entitled “Programming Method for Write Buffer and Double Word Flash Programming,” to Amidon et al.; and
U.S. patent application serial No. ______; filed on Jun. 15, 2006, entitled “Flash Programmer for Programming NAND Flash and NOR/NAND Combined Flash,” to Amidon et. al.

### FIELD

The present invention relates generally to programming programmable devices, and more particularly, relates to programming flash devices in parallel during in-circuit testing.

### BACKGROUND

Manufacturers of high volume products have several options for programming programmable devices in a product. One option is to program the devices prior to assembling and soldering the devices to a printed circuit board (PCB). Another option is to program the devices after they are soldered to the PCB.

On board programming is generally more flexible due to the nature of programming the parts later in the manufacturing process. Less potential rework exists when the customization of the product occurs later in the process. Sending out programmable devices for programming can cause a two to ten day delay. This delay creates a need for up to ten days of pre-programmed devices on-hand. When a programming change occurs, all of the pre-programmed devices on-hand and in the pipeline require re-programming. Programming the devices on board reduces this two to ten day supply down to zero, reducing the need for re-programming to just the PCBs that are already produced, which would be required in either scenario.

There are several options for programming devices on board. A common method is to utilize an In-Circuit Tester (ICT) to download the code to the device. In a high volume-manufacturing environment, the time of download plus the actual ICT test time must be within the time requirements of the manufacturing process or a bottleneck in the process may form at ICT. Improvements to the flash programming speed may eliminate this bottleneck. Programming done within the required timeframe at the ICT is nearly free, while programming out of house or on separate platforms can be expensive. If the programming is done using the ICT, when in-circuit testing is already performed, the cost may be close to zero. The speed of programming is critical to obtaining this near zero cost.

The ability to program several devices at the same time reduces the programming time per device by dividing the total programming time by the number of devices programmed in that time. Some ICT systems are capable of testing more than one device at a time. For example, some ICT systems offer a method to add hardware to the system to implement parallel capability. However, this equipment can be very expensive and can parallel program only a limited number of devices.

Therefore, a method for parallel programming a larger number of flash devices during in-circuit testing would be beneficial.

### SUMMARY

A method and system for parallel programming flash devices during in-circuit testing is described. A method for parallel programming flash memory during in-circuit testing includes identifying which of a plurality of printed circuit boards connected to a test fixture has a flash device that passed in-circuit testing and parallel programming the flash devices that passed in-circuit testing. Identifying which of a plurality of printed circuit boards connected to a test fixture has a flash device that passed in-circuit testing may include receiving a signal from an in-circuit tester.

Parallel programming the flash devices that passed in-circuit testing may include enabling buffers in the test fixture that correspond to the printed circuit boards having a flash device that passed in-circuit testing, disabling buffers in the test fixture that correspond to the printed circuit boards having a flash device that failed in-circuit testing, and passing programming information from the in-circuit tester through the enabled buffers. The programming information may include address, data, and control signals for programming the flash devices that passed in-circuit testing.

Enabling the buffers electrically connects the in-circuit tester to the printed circuit boards corresponding to the enabled buffers. Disabling the buffers prevents the flash device on the corresponding printed circuit board from being programmed. Additionally, disabling the buffers may protect the in-circuit tester from the flash devices that failed in-circuit testing.

Parallel programming the flash devices that passed in-circuit testing may include connecting a number of parallel programming devices within the test fixture. The number of parallel programming devices equals the number of printed circuit boards connected to the test fixture. The parallel programming devices provide a communication path between an in-circuit tester and the plurality of printed circuit boards that facilitates parallel programming of the flash devices that passed in-circuit testing.

The method may also include monitoring for completion of the parallel programming of the flash devices that passed in-circuit testing. Monitoring for completion of the parallel programming may include monitoring a read busy line and/or reading a status register in the flash device.

A system for parallel programming flash memory during in-circuit testing includes a processor, data storage, and machine language instructions stored in the data storage executable by the processor to receive a signal from an in-circuit tester identifying which of a plurality of printed circuit boards connected to a test fixture has a flash device that passed in-circuit testing, enable buffers in the test fixture that correspond to the printed circuit boards having a flash device that passed in-circuit testing, disable buffers in the test fixture that correspond to the printed circuit boards having a flash device that failed in-circuit testing, and pass programming information from the in-circuit tester through the enabled buffers to parallel program the flash devices that passed in-circuit testing.

Another system for parallel programming flash memory during in-circuit testing includes an in-circuit tester designed to perform in-circuit testing of a plurality of printed circuit boards. The in-circuit tester includes a test fixture that connects to the plurality of printed circuit boards during testing. The system also includes a plurality of circuits located within the test fixture. Each the plurality of circuits corresponds to one of the plurality of printed circuit boards. Additionally, each of the circuits includes a processor that receives signals from the in-circuit tester indicating which of the plurality of printed circuit boards have a flash device to be programmed and at least one buffer that the processor enables to allow the in-circuit tester to program the flash devices to be programmed. The in-circuit tester programs the flash devices to be programmed in parallel.

The processor may disable the at least one buffer if the flash device failed in-circuit testing. The at least one buffer may be an address buffer, a data buffer, and/or a control buffer. The processor may enable the at least one buffer until the programming of the flash device has completed. The processor may determine that the programming of the flash device has completed by monitoring a read busy line and/or reading a status register in the flash device. Each of the circuits may also have a bus for communicating with the in-circuit tester and a bus for communicating with the corresponding printed circuit board.

These as well as other aspects and advantages will become apparent to those of ordinary skill in the art by reading the following detailed description, with reference where appropriate to the accompanying drawings. Further, it is understood that this summary is merely an example and is not intended to limit the scope of the invention as claimed.

### BRIEF DESCRIPTION OF THE DRAWINGS

Presently preferred embodiments are described below in conjunction with the appended drawing figures, wherein like reference numerals refer to like elements in the various figures, and wherein:

FIG. 1 is a block diagram of an in-circuit tester, according to an example;

FIG. 2 is a block diagram of a circuit board panel, according to an example;

FIG. 3 is a block diagram showing a set of parallel programming devices located in a test fixture, according to an example;

FIG. 4 is a block diagram showing a set of parallel programming devices located in a test fixture, according to another example;

FIG. 5 is a block diagram showing parallel programming; according to an example;

FIG. 6 is a block diagram showing parallel programming, according to another example;

FIG. 7 is a block diagram showing parallel programming, according to another example; and

FIG. 8 is a block diagram of a parallel programming device, according to an example.

### DETAILED DESCRIPTION

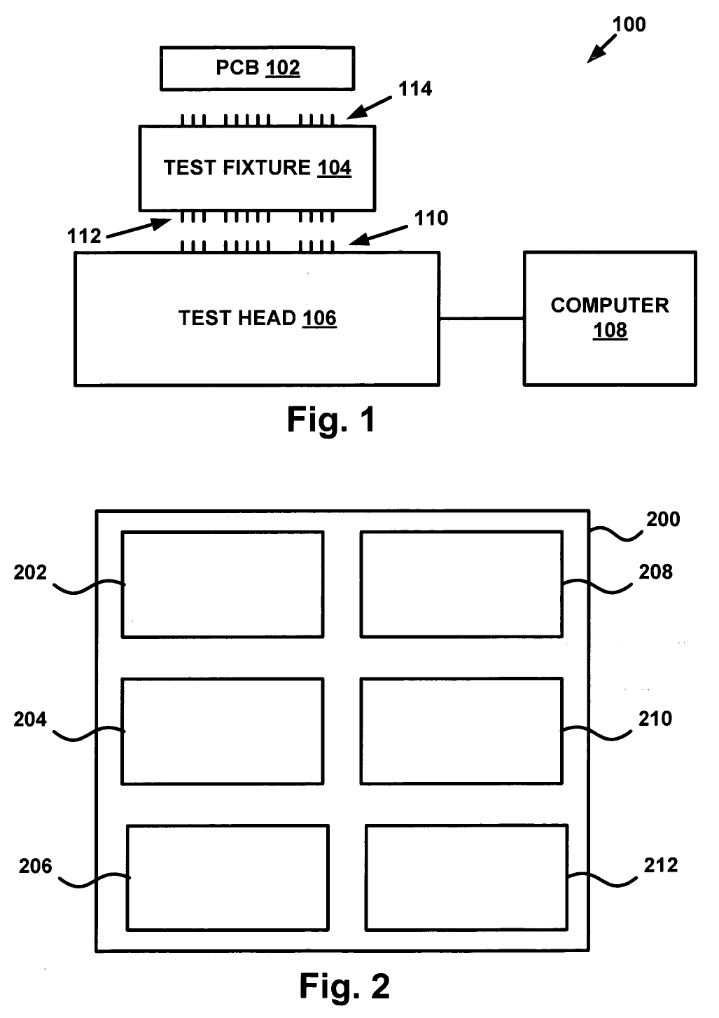

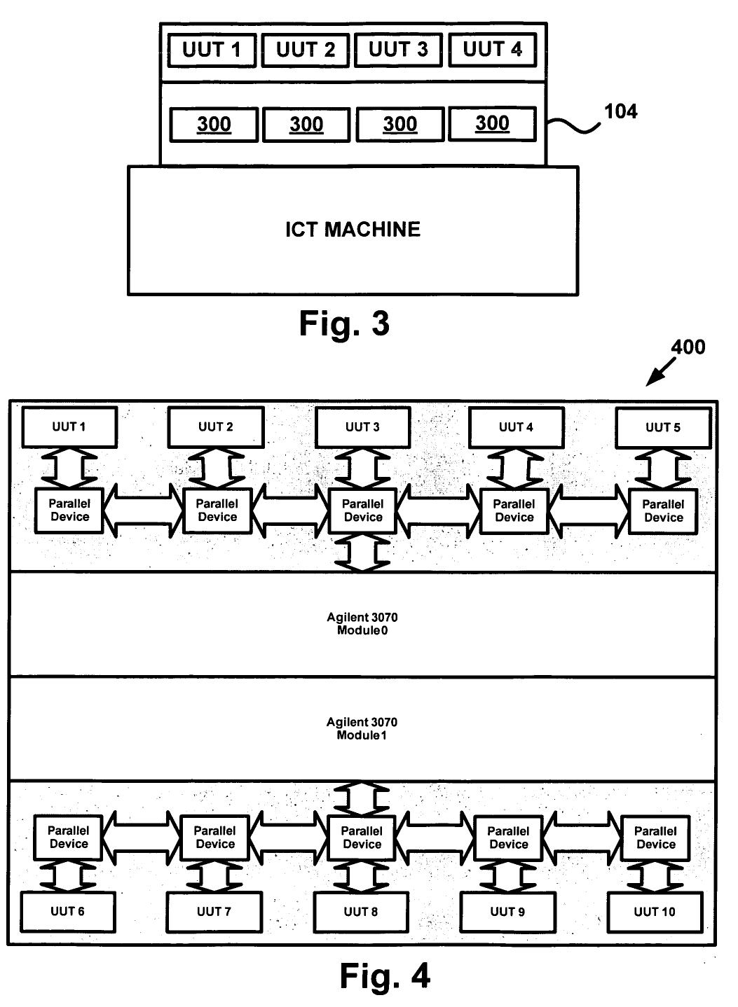

FIG. 1 is a block diagram of an In-Circuit Tester (ICT) 100. As a non-limiting example, the ICT 100 may be an HP/Agilent 3070. Typically, the ICT 100 includes a test fixture 104, a test head 106, and a computer 108. The combination of the test head 106 and the computer 108 is sometimes referred as the ICT machine, and the test head 106 and the computer 108 may be co-located as shown in FIG. 3.

The ICT 100 may be designed to test a printed circuit board (PCB) 102 or a circuit board panel that includes more than one PCB, such as the circuit board panel 200 described with reference to FIG. 2. For example, the ICT 100 may test the PCB 102 or the circuit board panel 200 for shorts, opens, current draw, tolerances, and/or functionality. The test fixture 104 may be customized for each PCB design.

The computer 108 includes a processor, data storage, and machine language instructions stored in the data storage executable by the processor as is well known in the art. The computer 108 is not limited to having any particular type of processor, data storage, or instruction format. The computer 108 may select a test application dedicated to a particular type of circuit board design. Generally, the test application drives information to the test head 106.

The test head 106 receives the information from the computer 108 and responds by driving a number of test pins 110 on the test head 106, including those test pins 110 that provide data and address information to the test fixture 104. The test fixture 104 includes contacts 112 aligned with at least some of the test pins 110, which are routed to corresponding spring probes 114. The spring probes 114 are positioned in such a manner so that when the PCB 102 or the circuit board panel 200 is placed on the test fixture 104, the spring probes 114 establish contact with various test pads (not shown) located at a bottom surface of the PCB 102 or the circuit board panel 200. These test pads are routed to various pins of the components attached to the PCB 102 or the circuit board panel 200.

The processor in the computer 108 may be a vector processor, which facilitates testing the PCB 102 or the circuit board panel 200. The vector processor generates an input that is sent to the PCB 102 or the circuit board panel 200, and in response, the vector processor expects a particular output from the PCB 102 or the circuit board panel 200. If the vector processor receives the expected output, then that particular test pattern may be considered as a passing test. Otherwise, the vector processor may identify a test failure, which may indicate that there is a problem with the PCB 102 or the circuit board panel 200. While the vector processor provides efficient testing of the PCB 102 or the circuit board panel 200, this type of processor is unable to make a decision.

The ICT 100 may also be used to program memory components on the PCB 102 or the circuit board panel 200. For example, the ICT 100 may be used to program flash devices located on the PCB 102 or the circuit board panel 200. Generally, the ICT 100 sends programming commands to the flash device, applies the address and data to be programmed, and then polls to verify completion of the programming. Typically, each flash device type has specific instructions for programming that is provided to the ICT 100.

FIG. 2 is a block diagram of the circuit board panel 200. The circuit board panel 200 may include more than one PCB, such as PCBs 202-212. While the circuit board panel 200 is shown with six PCBs 202-212, the circuit board panel 200 may have more or less than six PCBs. The PCBs 202-212 are generally multiple instances of the same circuit manufactured as a panel of circuit boards for manufacturing efficiency. The PCBs 202-212 may be separated by cutting or breaking after manufacture and test, to provide separate products. For example, each of the PCBs 202-212 may be a modem board.

It would be beneficial to implement a parallel programming device that programs all of the flash devices contained on the PCBs located on the circuit board panel 200 (e.g., units under test (UUT)) substantially simultaneously. A multiple-module ICT may have a bus for carrying signals from a specific module to the UUTs that the module tests. Specific flash devices may have failed one or more standard ICT tests and may not be capable of being programmed. The failed flash device should not be programmed. Thus, the parallel programming device should be capable of disabling the programming of specific flash devices if they have failed ICT testing. Additionally, the flash devices that are not programmed should not impede the programming of the other flash devices.

FIG. 3 is a block diagram showing a set of parallel programming devices 300 located in the test fixture 104. Each of the parallel programming devices 300 is a self-contained device having a small footprint, which allows the parallel programming devices 300 to be installed within the test fixture 104 with limited probe interference in the test fixture 104. The parallel programming devices 300 may be connected to the test fixture 104 using a standard connector; using either a direct connection or by wire wrapping to a probe socket in the test fixture 104; or using any other method for adding a circuit to the test fixture 104.

Preferably, the test fixture 104 is designed to have an additional connector (not shown) that the parallel programming devices 300 can connect to. As a result, the parallel programming devices 300 may be described as a “plug-in” device, which may be easily inserted and removed from the test fixture 104 without impacting the operation of the ICT machine. The connecter may be wired to the spring probes 114, which are connected to the contacts 112 in the test fixture 104.

FIG. 4 is a block diagram 400 showing another view of the set of the parallel programming devices 300 (depicted as “Parallel Device”) located in the test fixture 104. In this example, ten UUTs are located in an HP/Agilent 3070 two-module system connected in parallel through the parallel programming devices 300. The gray area in FIG. 4 denotes the contents of the test fixture 104.

While FIG. 4 depicts a two-module system, The ICT 100 may be a one-module system or have more than two modules. The two-module system in FIG. 4 shows that there may be two (or more) parallel branches of parallel devices. It may be desirable to have parallel branches to provide separation of ground planes between module 1 and module 2, if necessary. If the ICT 100 contains only one module or computer 108, the parallel devices may be connected in parallel to the one module.

As seen in FIGS. 3-4, a single parallel programming device 300 is dedicated to each UUT. In the example depicted in FIG. 3, there are four parallel programming devices 300, while in the example depicted in FIG. 4, there are ten parallel programming devices 300. While the parallel programming devices 300 are depicted as stand-alone devices, it is understood that the parallel programming devices 300 may be packaged together in one or more packages.

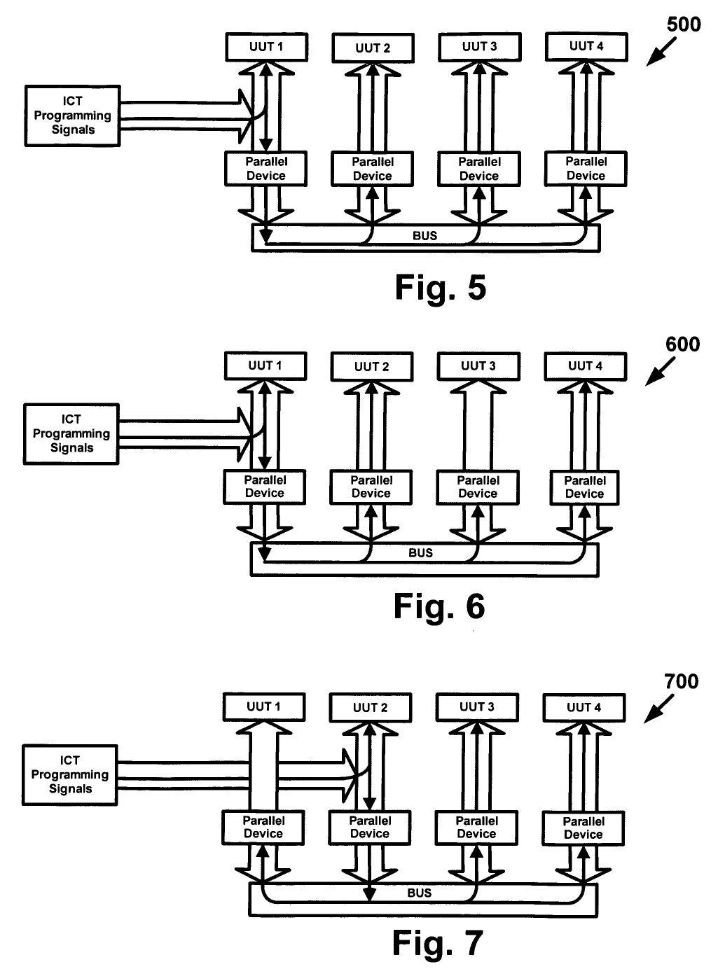

The parallel programming devices 300 are engaged prior to starting the process to program the flash devices. The individual parallel programming devices 300 apply signaling from the ICT machine bus to the flash device on the UUT as appropriate. FIGS. 5-7 provide more description regarding the communication between the parallel programming devices 300, the ICT machine, and the UUTs.

FIG. 5 is a block diagram 500 that shows how the parallel programming devices 300 provide parallel programming of the flash devices during ICT. In this example, the input signals from the ICT machine are sent on a bus corresponding to UUT 1. The bus is also connected to the first parallel programming device 300 connected to UUT 1. The signals on the bus are then connected to the other UUTs through the other corresponding parallel programming devices 300.

If any of the flash devices (UUT 2, UUT 3, or UUT 4 in this example) did not pass ICT testing and/or do not require programming, the parallel programming device 300 does not connect that UUT to the bus. This prevents the flash device from being programmed as well as protects the bus from possible shorts or device problems associated with that UUT. FIGS. 6 and 7 provide examples with respect to the parallel programming if one of the flash devices has failed an in-circuit test.

FIG. 6 is a block diagram 600 showing parallel programming when a flash device on UUT 3 has failed an ICT test. The parallel programming device 300 associated with UUT 3 disconnects UUT 3 from the bus to prevent programming of this UUT. FIG. 7 is a block diagram 700 showing parallel programming when a flash device on UUT 1 has failed an ICT test. In this example, the ICT machine drives signals into UUT 2, which connects those signals to the bus. The parallel programming device 300 connected to UUT 1 receives the signals from the bus, but does not connect the bus to UUT 1.

As described, the parallel programming devices 300 drive signals from the ICT machine to the UUTs that have flash devices that have passed ICT testing. If more than one UUT has flash devices that have failed ICT testing, the corresponding parallel programming devices 300 do not drive the signals to the those UUTs. As a result, there are numerous combinations of flash devices that are parallel programmed by the parallel programming devices 300 based on which flash devices have passed ICT testing.

Typically, the determination of when the flash program can proceed to the next address and data is determined by a response from the flash device indicating that it has complete its programming. There are two common methods to determine when a flash device has completed an operation: 1) use a hardware signal commonly referred to as the ready busy signal; and 2) directly read the status register of the flash device itself.

To implement the Ready Busy Method, the ready busy line may be pulled low when the flash device is performing an operation and returned to the high state when the operation is complete. By waiting for the ready busy line to return high, the parallel programming device 300 may determine when the next address and data programming can occur. The parallel programming device 300 may include logic to tie together the ready busy lines from all of the flash devices being programmed. The single output of this logic signals that all flash devices have completed an operation and are ready for the next operation.

To implement the Status Register Method, the parallel program device 300 reads the status register by incorporating a microprocessor or a logic device to communicate with the flash devices and then respond through the same ready busy interface described above. When each program operation starts, the processor may pull the same line that is connected to the ready busy line low. When the status register reports that the flash device has completed its operation, the microprocessor or logic device can pull the ready busy line high. This essentially provides similar signaling to the programming source as the Ready Busy Method and, as a result, the programming code may be substantially the same.

To select either the Ready Busy Method or the Status Register Method for a particular flash device, a jumper on the hardware or a signal may be used to identify which method to use. The microprocessor or logic device may process this signal or jumper setting, and respond accordingly.

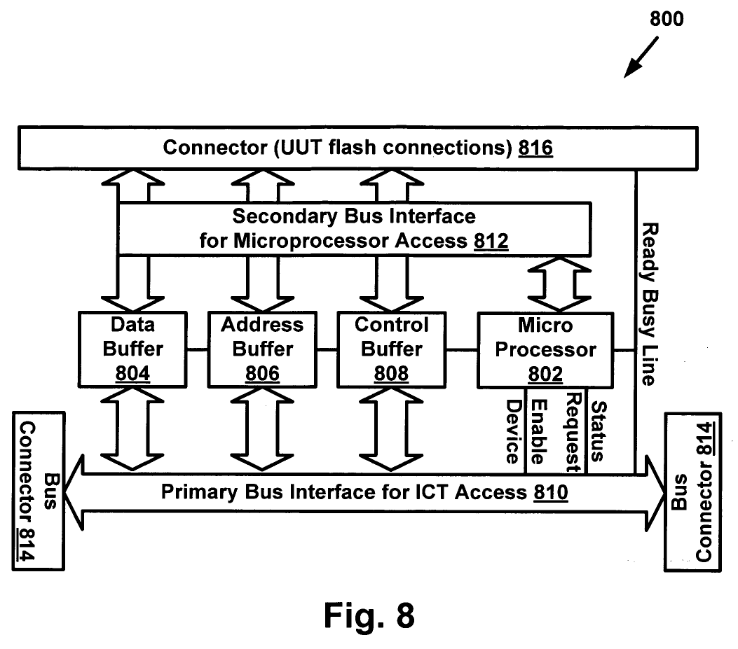

FIG. 8 is a block diagram 800 of a parallel processing device 300. The parallel processing device 300 includes a microprocessor 802, a data buffer 804, an address buffer 806, a control buffer 808, a primary bus interface 810, a secondary bus interface 812, an ICT bus connector 814, and a UUT connector 816. The parallel processing device 300 may have other components as well.

Additionally, the parallel processing device 300 may have a different design that provides substantially the same functionality. For example, if all of the UUTs have known good flash devices, the microprocessor 802 and/or the buffers 804-808 may be unnecessary. Instead, a direct wire connection between the primary bus interface 810 and the secondary bus interface 812 may be used.

The microprocessor 802 controls the operation of the parallel processing device 300. The microprocessor 802 obtains signals from the ICT machine via the ICT bus connector 814 and the primary bus interface 810. The signals may indicate that the parallel processing device 300 should either enable or disable the buffers 804-808. When the buffers 804-808 are enabled, the microprocessor 802 may allow signaling from the ICT machine to program flash devices connected to the UUT connector 816 via the secondary bus interface 812. The microprocessor 802 may allow access to the UUT until the parallel programming of the flash devices is completed.

By using multiple parallel processing devices 300 in parallel, the ICT machine can program flash devices in parallel, thus, dividing the flash time per device by the number of devices in parallel. While theoretically there may be no limit as to the number of parallel processing devices 300 that can be implemented in parallel, the test fixture 104 may have connection and/or space limitations, which may limit the number of flash devices that can be programmed at the same time.

The set of parallel processing devices 300 allows the flash devices to be programmed at substantially the same time without additional resources from the ICT machine. The following example is described using an HP/Agilent 3070 two-module machine, which is capable of testing and flashing two boards in parallel. If the circuit board panel 200 has ten boards and the flash time per device is 15 seconds, the HP/Agilent 3070 two-module machine requires 75 seconds to program all ten devices: ten devices programmed two at a time. By using the parallel processing devices 300 in the test fixture 104, the HP/Agilent 3070 can flash all ten boards in parallel in 15 seconds. As a result, the time to program the flash devices has been dramatically reduced without having to add additional modules to the HP/Agilent tester.

Other methods of parallel programming may also be used and the invention is not limited to the bus-type methodology described. For example, the ICT machine may transfer program code to each of the parallel programming devices 300 in a sequential manner. In this way, several parallel programming devices 300 may program flash devices at approximately the same time, although the start time of the programming may be delayed by the program transfer time.

It should be understood that the illustrated embodiments are examples only and should not be taken as limiting the scope of the present invention. For example, while the flash programmer 300 has been described herein with reference to the HP/Agilent ICT, the flash programmer 300 can be implemented with other ICTs, such as the ICTs manufactured by Teradyne, Genrad, and others. The claims should not be read as limited to the described order or elements unless stated to that effect. Therefore, all embodiments that come within the scope and spirit of the following claims and equivalents thereto are claimed as the invention.

We claim:

1. A method for parallel programming flash memory during in-circuit testing, comprising in combination:
identifying which of a plurality of printed circuit boards connected to a test fixture has a flash device that passed in-circuit testing; and
parallel programming the flash devices that passed in-circuit testing.

2. The method of claim 1, wherein identifying which of a plurality of printed circuit boards passed in-circuit testing includes receiving a signal from an in-circuit tester.

3. The method of claim 1, wherein parallel programming the flash devices that passed in-circuit testing includes
enabling buffers in the test fixture that correspond to the printed circuit boards having a flash device that passed in-circuit testing;
disabling buffers in the test fixture that correspond to the printed circuit boards having a flash device that failed in-circuit testing; and
passing programming information from the in-circuit tester through the enabled buffers.

4. The method of claim 3, wherein enabling the buffers electrically connects the in-circuit tester to the printed circuit boards corresponding to the enabled buffers.

5. The method of claim 3, wherein disabling the buffers prevents the flash device on the corresponding printed circuit board from being programmed.

6. The method of claim 3, wherein disabling the buffers protects the in-circuit tester from the flash devices that failed in-circuit testing.

7. The method of claim 3, wherein the programming information includes address, data, and control signals for programming the flash devices that passed in-circuit testing.

8. The method of claim 1, wherein parallel programming the flash devices that passed in-circuit testing includes connecting a number of parallel programming devices within the test fixture, wherein the number of parallel programming devices equals the number of printed circuit boards connected to the test fixture.

9. The method of claim 8, wherein the parallel programming devices provide a communication path between an in-circuit tester and the plurality of printed circuit boards that facilitates parallel programming of the flash devices that passed in-circuit testing.

10. The method of claim 1, further comprising monitoring for completion of the parallel programming of the flash devices that passed in-circuit testing.

11. The method of claim 10, wherein monitoring for completion of the parallel programming includes monitoring a read busy line.

12. The method of claim 10, wherein monitoring for completion of the parallel programming includes reading a status register in the flash device.

13. A system for parallel programming flash memory during in-circuit testing, comprising in combination:
a processor;
data storage; and
machine language instructions stored in the data storage executable by the processor to:
receive a signal from an in-circuit tester identifying which of a plurality of printed circuit boards connected to a test fixture has a flash device that passed in-circuit testing;
enable buffers in the test fixture that correspond to the printed circuit boards having a flash device that passed in-circuit testing;
disable buffers in the test fixture that correspond to the printed circuit boards having a flash device that failed in-circuit testing; and
pass programming information from the in-circuit tester through the enabled buffers to parallel program the flash devices that passed in-circuit testing.

14. A system for parallel programming flash memory during in-circuit testing, comprising in combination:
an in-circuit tester designed to perform in-circuit testing of a plurality of printed circuit boards, wherein the in-circuit tester includes a test fixture that connects to the plurality of printed circuit boards during testing; and
a plurality of circuits located within the test fixture, wherein each the plurality of circuits corresponds to one of the plurality of printed circuit boards, and wherein each of the circuits includes
a processor that receives signals from the in-circuit tester indicating which of the plurality of printed circuit boards have a flash device to be programmed; and
at least one buffer that the processor enables to allow the in-circuit tester to program the flash devices to be programmed;
wherein the in-circuit tester programs the flash devices to be programmed in parallel.

15. The system of claim 14, wherein the processor may disable the at least one buffer if the flash device failed in-circuit testing.

16. The system of claim 14, wherein the at least one buffer includes an address buffer, a data buffer, and a control buffer.

17. The system of claim 14, wherein the processor may enable the at least one buffer until the programming of the flash device has completed.

18. The system of claim 17, wherein the processor determines that the programming of the flash device has completed by monitoring a read busy line.

19. The system of claim 17, wherein the processor determines that the programming of the flash device has completed by reading a status register in the flash device.

20. The system of claim 14, wherein each of the circuits further including a bus for communicating with the in-circuit tester and a bus for communicating with the corresponding printed circuit board.
